(19) United States
(12) Patent Application Publication
(10) Pub. No.: US 2024/0055469 A1
(43) Pub. Date: Feb. 15, 2024

(54) NON-VOLATILE MEMORY DEVICE

(71) Applicant: Samsung Electronics Co., Ltd., Suwon-si (KR)

(72) Inventors: Chang-Bum KIM, Suwon-si (KR); Cheon An LEE, Suwon-si (KR); Sukkang SUNG, Suwon-si (KR)

(73) Assignee: Samsung Electronics Co., Ltd., Suwon-si (KR)

(21) Appl. No.: 18/305,752

(22) Filed: Apr. 24, 2023

(30) Foreign Application Priority Data
Aug. 12, 2022 (KR) 10-2022-0101607

(51) Int. Cl. H01L 21/02; H01L 23/00; H01L 25/065

(52) U.S. Cl. CPC H01L 28/90; H10B 41/10; H10B 43/27; H10B 41/27; H01L 24/08; H10B 80/00; H10B 43/10; H01L 25/0657; H01L 2924/1438; H01L 2225/06544; H01L 2924/1431; H01L 2224/08145

(57) ABSTRACT

The present disclosure relates to a semiconductor device, and more particularly, relates to a non-volatile memory device having a three-dimensional structure. The non-volatile memory device according to an embodiment of the present disclosure includes a first chip having a peripheral circuit therein and a second chip that is stacked on the first chip and that includes memory blocks. The second chip includes a common source line that has a plate shape and extends in first and second directions, first and second dummy common source lines disposed at a same height level as the common source line, an upper insulating layer that covers the common source line and the first and second dummy common source lines, and first and second dummy contact plugs extending in a third direction and that are electrically connected to the first and second dummy common source lines, respectively, and used as electrodes of a vertical capacitor.

### CROSS-REFERENCE TO RELATED APPLICATIONS

This application claims priority under 35 U.S.C. § 119 to Korean Patent Application No. 10-2022-0101607 filed on Aug. 12, 2022, in the Korean Intellectual Property Office, the disclosure of which is incorporated by reference herein in its entirety.

### BACKGROUND

Example embodiments of the present disclosure described herein relate to a semiconductor device, and more particularly, relate to a non-volatile memory device having a three-dimensional structure.

Memory devices are used to store data. The memory devices are classified into a volatile memory device and a non-volatile memory device. As an example of the non-volatile memory device, a flash memory device may be used in a mobile phone, a digital camera, a mobile computer device, a stationary computer device, and other devices. Recently, with the multi-functionalization of information and communication devices, high-capacity and high-integration memory devices have been desired.

### SUMMARY

Example embodiments of the present disclosure provide a vertical capacitor structure having large capacitance while minimizing an increase in chip size, and a non-volatile memory device including the same.

An example embodiment provides for non-volatile memory device comprising a first chip having a peripheral circuit therein; and a second chip stacked on the first chip, the second chip including memory blocks. The second chip includes a common source line having a plate shape, the common source line extending in first and second directions, first and second dummy common source lines at a same height level as the common source line, an upper insulating layer covering the common source line and the first and second dummy common source lines, and first and second dummy contact plugs extending in a third direction, the first and second dummy contact plugs being electrically connected to the first and second dummy common source lines, respectively, and used as electrodes of a vertical capacitor.

Another example embodiment provided for a non-volatile memory device comprising a first chip including a peripheral circuit region; and a second chip stacked on the first chip, the second chip including a cell region. The second chip includes a common source line having a plate shape, the common source line being extending in first and second directions, first and second dummy common source lines at a same height level as the common source line and electrically isolated from each other, an input/output contact plug on one side of the common source line and extending in a third direction perpendicular to the common source line to transfer a signal received from an input/output pad to the first chip, and first and second dummy contact plugs extending in the third direction and connected to the first and second dummy common source lines, respectively, the first and second dummy contact plugs having a same shape as the input/output contact plugs.

### BRIEF DESCRIPTION OF THE FIGURES

The above and other objects and features of the present disclosure will become apparent by describing in detail some example embodiments thereof with reference to the accompanying drawings.

FIG. 1 is a block diagram illustrating a non-volatile memory device according to some example embodiments of the present disclosure.

FIG. 2 is a layout diagram for describing one example of an arrangement of the non-volatile memory device of FIG. 1.

FIG. 3 is a plan view illustrating one example of region R of FIG. 2 according to some example embodiments of the present disclosure.

FIG. 4 illustrates one example of a sectional view taken along line I-I′ of FIG. 3.

FIG. 5 illustrates one example of a sectional view taken along line II-II′ of FIG. 3.

FIG. 6 is a sectional view illustrating one example of a first vertical capacitor structure of FIG. 5.

FIG. 7 is a plan view illustrating one example of region R of FIG. 2 according to some example embodiments of the present disclosure.

FIG. 8 illustrates one example of a sectional view taken along line II-II′ of FIG. 7.

FIG. 9 illustrates one example of a sectional view taken along line II-II′ of FIG. 3.

FIG. 10 is a plan view illustrating one example of region R of FIG. 2 according to some example embodiments of the present disclosure.

FIG. 11 illustrates one example of a sectional view taken along line II-II′ of FIG. 10.

FIG. 12 is a plan view illustrating one example of region R of FIG. 2 according to some example embodiments of the present disclosure.

FIG. 13 illustrates one example of a sectional view taken along line II-II′ of FIG. 12.

FIG. 14 illustrates another example of a sectional view taken along line II-II′ of FIG. 12.

FIG. 15 is a plan view illustrating one example of region R of FIG. 2 according to some example embodiments of the present disclosure.

FIG. 16 illustrates one example of a sectional view taken along line I-I′ of FIG. 15.

FIGS. 17 to 19 are views illustrating examples of region R of FIG. 2 according to some example embodiments of the present disclosure.

FIGS. 20 and 21 are sectional views illustrating one example of a non-volatile memory device according to some example embodiments of the present disclosure.

### DETAILED DESCRIPTION

Hereinafter, some example embodiments of the present disclosure will be described clearly and in detail to such an extent that those skilled in the art easily implement the present disclosure.

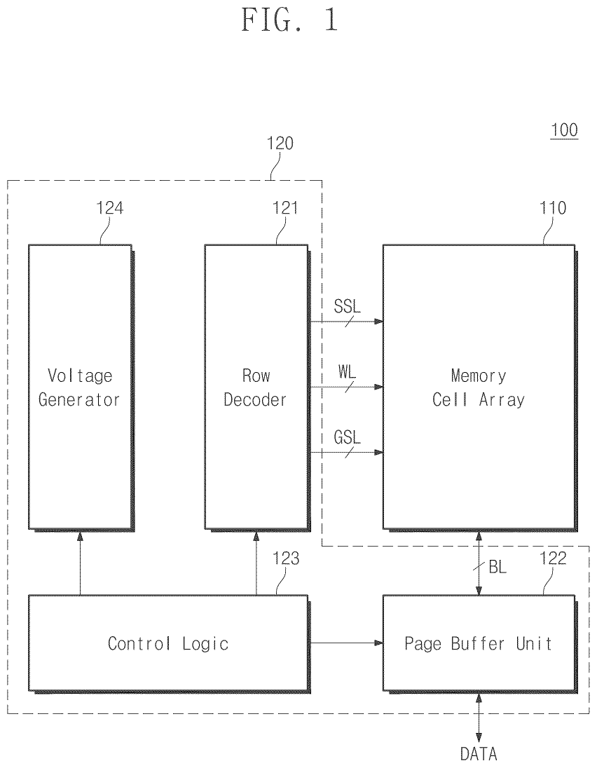

FIG. 1 is a block diagram illustrating a non-volatile memory device 100 according to some example embodiments of the present disclosure.

Referring to FIG. 1, the non-volatile memory device 100 may include a memory cell array 110 and a peripheral circuit 120, and the peripheral circuit 120 may include a row decoder 121, a page buffer unit 122, control logic 123, and a voltage generator 124.

The memory cell array 110 may be connected to the page buffer unit 122 through bit lines BL and may be connected to the row decoder 121 through word lines WL, string selection lines SSL, and ground selection lines GSL. The memory cell array 110 may include a plurality of memory cells. For example, the memory cells may be flash memory cells. However, the present disclosure is not limited thereto, and the plurality of memory cells may be resistive memory cells, such as resistive RAM (ReRAM), phase change RAM (PRAM), or magnetic RAM (MRAM).

The memory cell array 110 may include a three-dimensional memory cell array. The three-dimensional memory cell array may include a plurality of NAND strings, and each (or alternatively, at least one) of the NAND strings may include memory cells connected to respective word lines vertically stacked on a substrate.

In response to a row address signal, the row decoder 121 may select one of a plurality of memory blocks, may select one of word lines WL of the selected memory block, and may select one of the plurality of string selection lines SSL.

In response to a column address signal, the page buffer unit 122 may select some of the bit lines BL. The page buffer unit 122 may operate as a write driver or a sense amplifier depending on an operating mode.

The control logic 123 may control various types of operations in the non-volatile memory device 100 overall. For example, based on a command signal, an address signal, and a control signal, the control logic 123 may program data DATA in the memory cell array 110, or may read the data DATA from the memory cell array 110.

The voltage generator 124 may generate various types of voltages for performing a program operation, a read operation, and an erase operation on the memory cell array 110. For example, the voltage generator 124 may generate word line voltages, such as a program voltage, a read voltage, a pass voltage, an erase verification voltage, or a program verification voltage. In addition, the voltage generator 124 may further generate a string selection line voltage and a ground selection line voltage.

Meanwhile, although not illustrated, the peripheral circuit 120 may further include a data input/output circuit or an input/output interface, column logic, a pre-decoder, a temperature sensor, a command decoder, an address decoder, and the like.

In some example embodiments, the non-volatile memory device 100 may have a chip-to-chip (C2C) structure. The C2C structure may refer to a structure in which a first chip including the peripheral circuit 120 is manufactured on a first wafer, a second chip including the memory cell array 110 is manufactured on a second wafer different from the first wafer, and thereafter the first chip and the second chip are connected to each other by a bonding method.

In some example embodiments of the present disclosure, the non-volatile memory device 100 may form a vertical capacitor (hereinafter, referred to as the “VC”) using a dummy common source line (hereinafter, referred to as the “DCSL”) and a dummy contact plug (hereinafter, referred to as the “DCP”) formed within the second chip. The dummy common source line DCSL and the dummy contact plug DCP may be disposed in a region other than the region in which the memory cell array 110 is disposed within the second chip. The non-volatile memory device 100 may provide large capacitance without an increase in chip size, by forming the vertical capacitor VC using the dummy common source line DCSL and the dummy contact plug DCP.

In some example embodiments of the present disclosure, the dummy common source line DCSL may be formed by the same process as that of a common source line CSL. An overall process may be simplified by forming the dummy common source line DCSL using the formation process of the common source line CSL and forming the vertical capacitor VC using the dummy common source line DCSL. Furthermore, the dummy contact plug DCP may have the same shape as an input/output contact plug connected to a pad PAD. For example, the dummy contact plug DCP may be formed by a process that is the same as, or similar to, a process of forming the input/output contact plug. The overall process may be further simplified by forming the dummy contact plug DCP using the process that is the same as, or similar to, the process of forming the input/output contact plug.

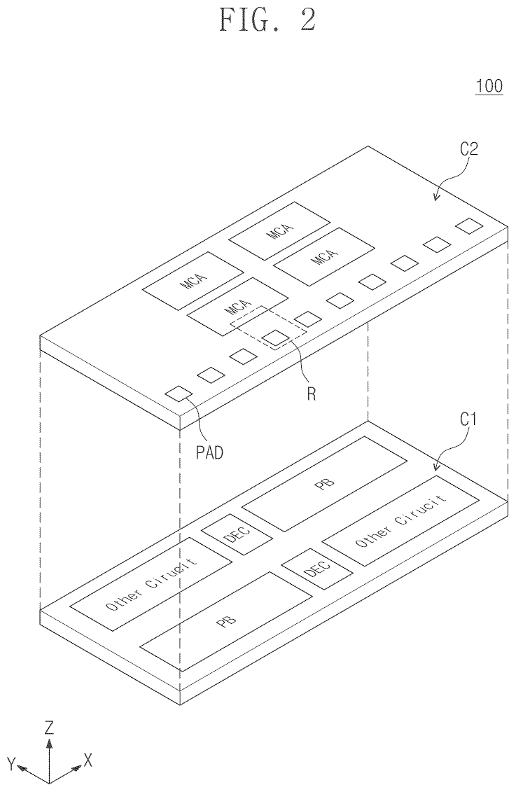

FIG. 2 is a layout diagram for describing one example of an arrangement of the non-volatile memory device 100 of FIG. 1.

Referring to FIG. 2, the non-volatile memory device 100 may include first and second chips C1 and C2 stacked in a vertical direction. The first chip C1 may include the peripheral circuit 120 of FIG. 1, the second chip C2 may include the memory cell array 110 of FIG. 1, and the first chip C1 and the second chip C2 may be connected to each other by a bonding method.

The first chip C1 may include a row decoder DEC, a page buffer PB, and other circuits OTHER CIRCUIT. The row decoder DEC may correspond to the row decoder 121 of FIG. 1, and the page buffer PB may be a region corresponding to the page buffer unit 122 of FIG. 1. Furthermore, the other circuits OTHER CIRCUIT may be regions including the control logic 124 and the voltage generator 124 of FIG. 1 and may include, for example, a latch circuit, a cache circuit, or a sense amplifier. In addition, the other circuits OTHER CIRCUIT may include an input/output buffer or a data input/output circuit.

At least some of the various circuit regions DEC, PB, and OTHER CIRCUIT of the first chip C1 may be disposed under memory cell arrays MCA of the second chip C2. For example, the page buffer PB and the other circuits OTHER CIRCUIT, when viewed on the plane, may be disposed to overlap the memory cell arrays MCA. However, this is illustrative, and circuits included in the first chip C1 and an arrangement thereof may be diversely changed. Accordingly, circuits disposed to overlap the memory cell arrays MCA may also be diversely changed.

The second chip C2 may include the memory cell arrays MCA and pads PAD. The memory cell arrays MCA may be spaced apart from each other and disposed in parallel or substantially parallel. However, this is illustrative, and the number of memory cell arrays MCA disposed in the second chip C2 and an arrangement thereof may be diversely changed.

The pads PAD may be disposed on at least one side of the memory cell arrays MCA. For example, the pads PAD may be disposed in a row along at least one edge of a second substrate structure S2. However, this is illustrative, and the pads PAD may be disposed in a row between the memory cell arrays MCA.

The pads PAD may be configured to transmit and receive an electrical signal with an external device. For example, the pads PAD may be connected with the input/output buffer among the other circuits OTHER CIRCUIT of the first chip C1 and may transmit data received through the input/output buffer to the external device.

In some example embodiments of the present disclosure, the dummy common source line DCSL and the dummy contact plug DCP that form the vertical capacitor VC may be disposed in a region other than the region in which the memory cell arrays MCA are disposed, among regions of the second chip C2. For example, when viewed on the plane, the dummy common source line DCSL and the dummy contact plug DCP may be disposed in a region between the pads PAD and the memory cell arrays MCA. Alternatively, when viewed on the plane, the dummy common source line DCSL and the dummy contact plug DCP may be disposed in a region between the pads PAD. In another case, when viewed on the plane, the dummy common source line DCSL and the dummy contact plug DCP may be disposed in a region at least partially overlapping the pads PAD.

As described above, by disposing the dummy common source line DCSL and the dummy contact plug DCP in a region other than the region in which the memory cell arrays MCA are formed, the non-volatile memory device 100 may provide large capacitance without an increase in chip size.

Hereinafter, various example embodiments of the present disclosure in which the vertical capacitor VC is formed in a region other than the region in which the memory cell arrays MCA are formed will be described in more detail.

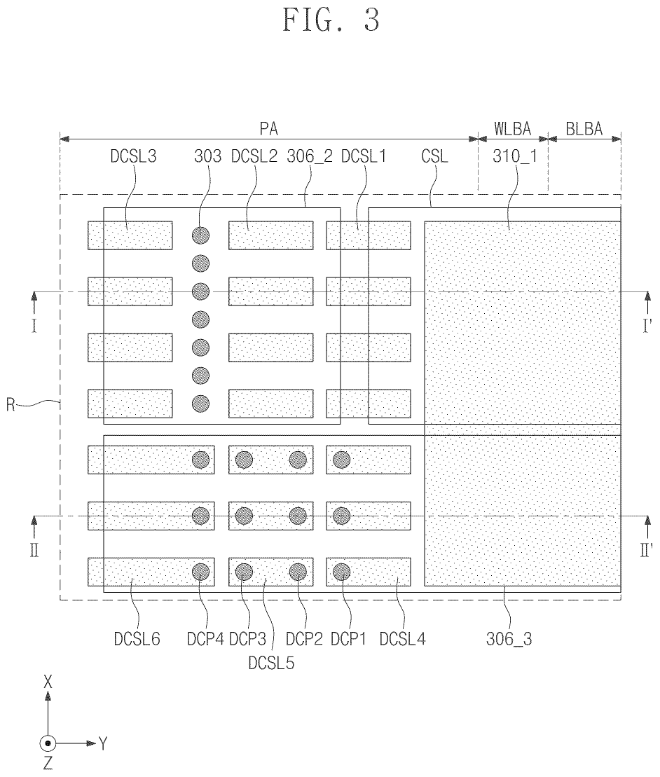

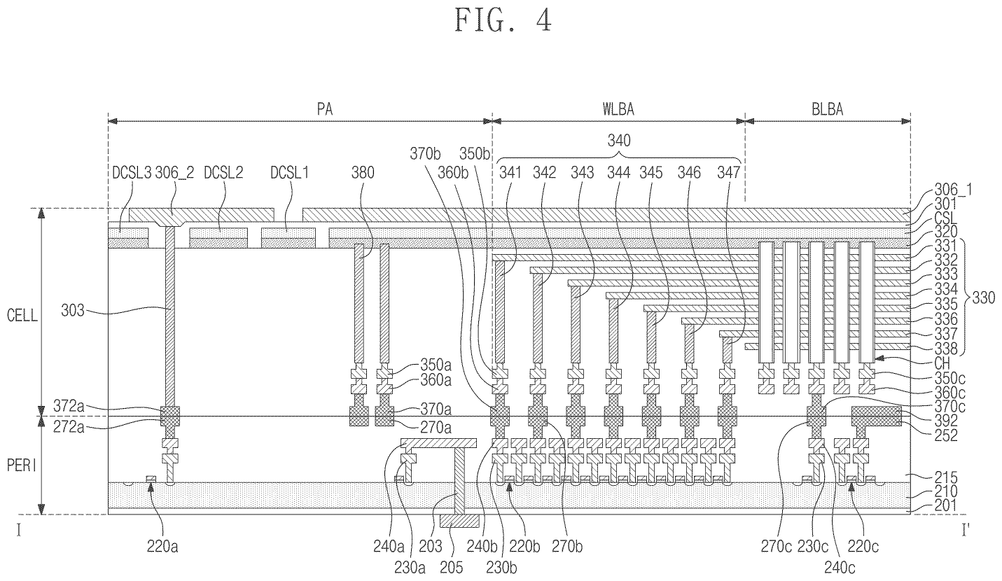

FIG. 3 is a plan view illustrating one example of region R of FIG. 2 according to some example embodiments of the present disclosure, and FIG. 4 illustrates one example of a sectional view taken along line I-I′ of FIG. 3.

Referring to FIGS. 3 and 4, the non-volatile memory device 100 may have a chip-to-chip (C2C) structure. Here, the C2C structure may refer to a structure in which at least one upper chip including a cell region CELL and a lower chip including a peripheral circuit region PERI are manufactured and connected to each other by a bonding method. For example, the bonding method may refer to a method of electrically connecting a bonding metal pattern formed on the uppermost metal layer of the upper chip and a bonding metal pattern formed on the uppermost metal layer of the lower chip. For example, in a case in which the bonding metal patterns are formed of or include copper (Cu), the bonding method may be a Cu-to-Cu bonding method. In another example, the bonding metal patterns may be formed of or include aluminum (Al) or tungsten (W).

The non-volatile memory device 100 may include at least one upper chip including a cell region. For example, as illustrated in FIG. 4, the non-volatile memory device 100 may be implemented to include one upper chip. However, this is illustrative, and the number of upper chips is not limited thereto. In the following description, an upper portion and a lower portion of the upper chip are defined based on before the upper chip is turned over. That is, an upper portion of the lower chip refers to an upper portion defined based on a +Z-axis direction, and the upper portion of the upper chip refers to an upper portion defined based on a −Z-axis direction.

Each (or alternatively, at least one) of the peripheral circuit region PERI and the cell region CELL of the non-volatile memory device 100 may include an external pad bonding region PA, a word line bonding region WLBA, and a bit line bonding region BLBA.

The peripheral circuit region PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal lines connecting the plurality of circuit elements 220a, 220b, and 220c may be provided in the interlayer insulating layer 215. For example, the plurality of metal lines may include first metal lines 230a, 230b, and 230c connected with the plurality of circuit elements 220a, 220b, and 220c, respectively, and second metal lines 240a, 240b, and 240c formed on the first metal lines 230a, 230b, and 230c. The plurality of metal lines may be formed of or include at least one of various conductive materials. For example, the first metal lines 230a, 230b, and 230c may be formed of or include tungsten having a relatively high electrical resistivity, and the second metal lines 240a, 240b, and 240c may be formed of or include copper having a relatively low electrical resistivity.

In this specification, only the first metal lines 230a, 230b, and 230c and the second metal lines 240a, 240b, and 240c are illustrated and described. However, without being limited thereto, one or more additional metal lines may be further formed on the second metal lines 240a, 240b, and 240c. In this case, the second metal lines 240a, 240b, and 240c may be formed of or include aluminum. At least some of the additional metal lines formed on the second metal lines 240a, 240b, and 240c may be formed of or include copper having a lower electrical resistivity than the aluminum of the second metal lines 240a, 240b, and 240c.

The interlayer insulating layer 215 may be disposed on the first substrate 210 and may include an insulating material, such as silicon oxide or silicon nitride.

The cell region CELL may include at least one memory block. The cell region CELL may include the common source line CSL having a plate shape and extending in a first direction (an X-axis direction) and a second direction (a Y-axis direction). The common source line CSL may include a metallic material and may include, for example, tungsten (W), aluminum (Al), copper (Cu), tungsten nitride (WN), tantalum nitride (TaN), a titanium nitride (TiN), or a combination thereof.

A second substrate 320 may be formed on the common source line CSL. In this case, the second substrate 320 may be formed of or include a material different from that of the first substrate 210. For example, the second substrate 210 may be provided as a polycrystalline layer or an epitaxial layer, or may include a doped region including impurities. However, this is illustrative. In some example embodiments, the second substrate 320 may be omitted without being formed, and only the common source line CSL may be provided. Alternatively, in some example embodiments, only the second substrate 320 may be provided without the common source line CSL. In this case, the second substrate 320 may perform a function of a common source line (e.g., is configured to operate as a common source line). Hereinafter, for convenience of description, it is assumed that the common source line CSL and the second substrate 210 overlapping the common source line CSL function as a common source line together (e.g., are configured to operate as a common source line).

A plurality of word lines 330 (331 to 338) may be stacked on the second substrate 320 in a direction (a Z-axis direction) perpendicular to or substantially perpendicular to a top surface of the second substrate 320. String selection lines and a ground selection line may be disposed on and under the word lines 330, and the plurality of word lines 330 may be disposed between the string selection lines and the ground selection line.

In the bit line bonding region BLBA, a channel structure CH may extend in a direction (the Z-axis direction) perpendicular to or substantially perpendicular to a top surface of the common source line CSL and may penetrate the word lines 330, the string selection lines, and the ground selection line. The channel structure CH may include a data storage layer, a channel layer, and a buried insulating layer, and the channel layer may be electrically connected with a first metal line 350c and a second metal line 360c. For example, the second metal line 360c may be a bit line and may be connected to the channel structure CH through the first metal line 350c. In some example embodiments, the bit line 360c may extend in the first direction (the X-axis direction) parallel to or substantially parallel to the top surface of the common source line CSL.

Furthermore, in the bit line bonding region BLBA, an upper metal pattern 252 may be formed on the uppermost metal layer of the peripheral circuit region PERI, and an upper metal pattern 392 having the same shape as the upper metal pattern 252 may be formed on the uppermost metal layer of the cell region CELL. The upper metal pattern 392 of the cell region CELL and the upper metal pattern 252 of the peripheral circuit region PERI may be electrically connected to each other by a bonding method. In the bit line bonding region BLBA, the bit line 360c may be electrically connected with a page buffer included in the peripheral circuit region PERI. For example, some of the circuit elements 220c of the peripheral circuit region PERI may provide a page buffer, and the bit line 360c may be electrically connected with the circuit elements 220c, which provide the page buffer, through an upper bonding metal 370c of the cell region CELL and an upper bonding metal 270c of the peripheral circuit region PERI.

Continuously referring to FIGS. 3 and 4, in the word line bonding region WLBA, the word lines 330 of the cell region CELL may extend in the second direction (the Y-axis direction) parallel to or substantially parallel to the top surface of the common source line CSL and may be connected with a plurality of cell contact plugs 340 (341 to 347). A first metal line 350b and a second metal line 360b may be sequentially connected to upper portions of the cell contact plugs 340 connected to the word lines 330. In the word line bonding region WLBA, the cell contact plugs 340 may be connected with the peripheral circuit region PERI through an upper bonding metal 370b of the cell region CELL and an upper bonding metal 270b of the peripheral circuit region PERI.

The cell contact plugs 340 may be electrically connected with a row decoder included in the peripheral circuit region PERI. For example, some of the circuit elements 220b of the peripheral circuit region PERI may provide a row decoder, and the cell contact plugs 340 may be electrically connected with the circuit elements 220b, which provide the row decoder, through the upper bonding metal 370b of the cell region CELL and the upper bonding metal 270b of the peripheral circuit region PERI. In some example embodiments, an operating voltage of the circuit elements 220b that provide the row decoder may differ from an operating voltage of the circuit elements 220c that provide the page buffer. For example, the operating voltage of the circuit elements 220c that provide the page buffer may be greater than the operating voltage of the circuit elements 220b that provide the row decoder.

In the external pad bonding region PA, common source line contact plugs 380 may be disposed in the direction (the Z-axis direction) perpendicular to or substantially perpendicular to the top surface of the common source line CSL. The common source line contact plugs 380 may be formed of or include a conductive material, such as metal, a metal compound, or doped poly-silicon. The common source lien contact plugs 380 of the cell region CELL may be electrically connected with the common source line CSL. A first metal line 350a and a second metal line 360a may be stacked (e.g., sequentially stacked) on an upper portion of the common source line contact plug 380 of the cell region CELL. Furthermore, the common source line contact plug 380 may be connected with the peripheral circuit region PERI through an upper bonding metal 370a of the cell region CELL and the upper bonding metal 270b of the peripheral circuit region PERI.

In the external pad bonding region PA, a lower insulating layer 201 may be formed under the first substrate 210 to cover a bottom surface of the first substrate 210, and a first input/output pad 205 may be formed on the lower insulating layer 201. The first input/output pad 205 may be connected with at least one of the plurality of circuit elements 220a, 220b, and 220c disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 and may electrically isolate the first input/output contact plug 203 from the first substrate 210.

In the external pad bonding region PA, first to third dummy common source lines DCSL1 to DCSL3 may be spaced apart from each other in the first direction (the X-axis direction) and the second direction (the Y-axis direction). Furthermore, the first to third dummy common source lines DCSL1 to DCSL3 may be spaced apart from the common source line CSL in the second direction (the Y-axis direction).

The first to third dummy common source lines DCSL1 to DCSL3 may be formed in the same process step as that of the common source line CSL. Accordingly, likewise to the common source line CSL, the first to third dummy common source lines DCSL1 to DCSL3 may include a metallic material and may be formed at the same height level as the common source line CSL.

An upper insulating layer 301 may be formed on bottom surfaces of the dummy common source liens DCSL1 to DCSL3 and the common source line CSL to cover the bottom surfaces of the dummy common source liens DCSL1 to DCSL3 and the common source line CSL. Furthermore, a side insulating layer may be disposed between the dummy common source lines DCSL1 to DCSL3 and the common source line CSL and may electrically isolate the dummy common source lines DCSL1 to DCSL3 and the common source line CSL. The upper insulating layer 301 and the side insulating layer may be integrally formed with each other, or may be formed through different process steps.

A first conductive layer 306_1 and a second conductive layer 3062 may be disposed on a bottom surface of the upper insulating layer 301. When viewed on the plane, the first conductive layer 306_1 may at least partially overlap the common source line CSL. Furthermore, the first conductive layer 306_1 may at least partially overlap the first dummy common source line DCSL1. The second conductive layer 3062 may overlap at least some of the dummy common source lines DCSL1 to DCSL3. However, this is illustrative, and an arrangement of the first conductive layer 306_1 and the second conductive layer 3062 may be diversely changed.

The second conductive layer 3062 may be used as an input/output pad. That is, a second input/output contact plug 303 may penetrate the upper insulating layer 301 and may be electrically connected to the second conductive layer 306_2 that is a second input/output pad, and the second conductive layer 306_2 may be connected with at least one of the plurality of circuit elements 220a, 220b, and 220c disposed in the peripheral circuit region PERI through the second input/output contact plug 303.

In the external pad bonding region PA, an upper metal pattern 372a may be formed on the cell region CELL, and an upper metal pattern 272a may be formed on the peripheral circuit region PERI. The upper metal pattern 372a of the cell region CELL and the upper metal pattern 272a of the peripheral circuit region PERI may be connected to each other by a bonding method.

As described with reference to FIGS. 3 and 4, at least portions of the dummy common source lines DCSL1 to DCSL3 may be formed to overlap the input/output pad 3062, and the dummy common source lines DCSL1 to DCSL3 may be in a floating state.

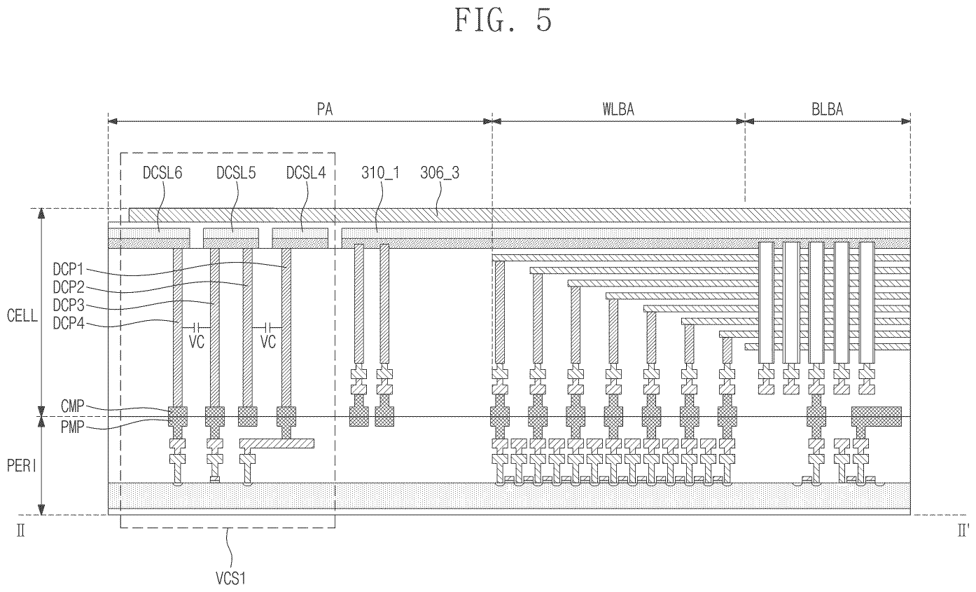

FIG. 5 illustrates one example of a sectional view taken along line II-II′ of FIG. 3. The sectional view of FIG. 5 is similar to the sectional view of FIG. 4. Accordingly, repetitive descriptions will hereinafter be omitted for the sake of brevity.

The non-volatile memory device 100 according to some example embodiments of the present disclosure may include the vertical capacitor VC in a region other than the region in which the second input/output pad 306_2 is disposed in the external pad bonding region PA. That is, the vertical capacitor VC may be formed by disposing dummy common source lines DCSL such that the dummy common source lines DCSL do not overlap the second input/output pad 3062 when viewed on the plane and disposing dummy contact plugs DCP on top surfaces of the dummy common source lines DCSL. As described above, by forming the vertical capacitor VC in the external pad bonding region PA of the cell region CELL in which a memory block is not disposed, the non-volatile memory device 100 may provide large capacitance without an increase in chip size.

In more detail, referring to FIGS. 3 and 5, a first vertical capacitor structure VCS1 may be provided in the external pad bonding region PA. The first vertical capacitor structure VCS1 may include dummy common source lines DCSL4 to DCSL6 and dummy contact plugs DCP1 to DCP4 formed in the cell region CELL and a circuit element formed in the peripheral circuit region PERI. The dummy common source lines DCSL4 to DCSL6 and the dummy contact plugs DCP1 to DCP4 of the cell region CELL may form the vertical capacitor VC.

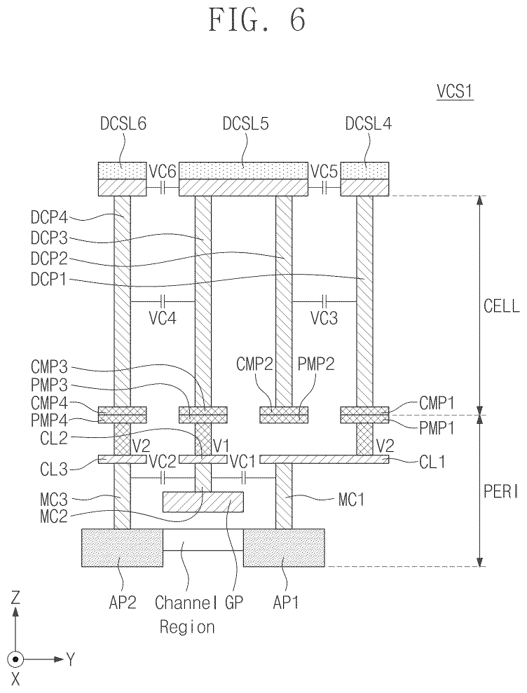

The dummy common source lines DCSL4 to DCSL6 may be formed in the same process step as that of the common source line CSL. Accordingly, the dummy common source lines DCSL4 to DCSL6 and the common source line CSL may include the same material and may have the same thickness at the same height level. However, while the common source line CSL is electrically connected to the channel structure CH, the dummy common source lines DCSL4 to DCSL6 may be electrically isolated from the channel structure CH. For example, the dummy common source lines DCSL4 to DCSL6 may be electrically isolated from the common source line CSL by the upper insulating layer 301 and thus may be electrically isolated from the channel structure CH. Furthermore, the dummy common source lines DCSL4 to DCSL6 may be electrically isolated from each other by the upper insulating layer 301. Alternatively, a common source line voltage may be provided to the common source line CSL, and a voltage may not be provided to the dummy common source lines DCSL4 to DCSL6, or a voltage different from the common source line voltage may be provided to the dummy common source lines DCSL4 to DCSL6. For example, as will be described with reference to FIG. 6, a first voltage V1 or a second voltage V2 may be provided to the dummy common source lines DCSL4 to DCSL6, and at least one of the first voltage V1 or the second voltage V2 may have a different voltage level from the common source line voltage.

The dummy contact plugs DCP1 to DCP4 extending in a third direction (the Z-axis direction) may be disposed on top surfaces of the dummy common source lines DCSL4 to DCSL6. For example, the first dummy contact plug DCP1 may be disposed on the top surface of the fourth dummy common source line DCSL4, the second and third dummy contact plugs DCP2 and DCP3 may be disposed on the top surface of the fifth dummy common source line DCSL5, and the fourth dummy contact plug DCP4 may be disposed on the top surface of the sixth dummy common source line DCSL6. The dummy common source lines DCSL4 to DCSL6 may be connected with at least one of the plurality of circuit elements disposed in the peripheral circuit region PERI through the dummy contact plugs DCP1 to DCP4.

The dummy contact plugs DCP1 to DCP4 may have the same shape as the second input/output contact plug 303 (refer to FIG. 4). That is, the dummy contact plugs DCP1 to DCP4 may be formed in a process step that is the same as, or similar to, that of the second input/output contact plug 303. Accordingly, the dummy contact plugs DCP1 to DCP4 may include the same material as the second input/output contact plug 303. For example, the dummy contact plugs DCP1 to DCP4 may be formed of or include a conductive material, such as metal, a metal compound, or doped poly-silicon.

The dummy contact plugs DCP1 to DCP4 may be electrically connected to metal patterns CMP formed in the uppermost metal layer of the cell region CELL. Metal patterns PMP having the same shape as the metal patterns CMP of the cell region CELL may be formed in the uppermost metal layer of the peripheral circuit region PERI to correspond to the metal patterns CMP of the cell region CELL. The metal patterns CMP of the cell region CELL and the metal patterns PMP of the peripheral circuit region PERI may be electrically connected to each other by a bonding method.

In some example embodiments according to the spirit and scope of the present disclosure, the dummy common source lines DCSL4 to DCSL6 and the dummy contact plugs DCP1 to DCP4 may be implemented as a portion of the first vertical capacitor structure VCS1.

Specifically, the dummy common source lines DCSL4 to DCSL6 and the dummy contact plugs DCP1 to DCP4 connected thereto may be electrically isolated from each other and may be used as electrodes of the capacitor. Since the dummy contact plugs DCP1, DCP2, and DCP3 extend in the third direction (the Z-axis direction) perpendicular to or substantially perpendicular to the first substrate 210, the capacitor formed by using the dummy contact plugs DCP1, DCP2, and DCP3 may be referred to as the vertical capacitor VC.

As described above with reference to FIGS. 3 to 5, the non-volatile memory device 100 according to some example embodiments of the present disclosure may include the dummy common source lines DCSL and the dummy contact plugs DCP disposed in the external pad bonding region PA, and the dummy common source lines DCSL and the dummy contact plugs DCP may be used as the vertical capacitor VC. Accordingly, the space of the external pad bonding region PA may be efficiently used without waste, and the non-volatile memory device 100 may provide large capacitance.

In addition, the dummy common source lines DCSL may be formed in the same process step as that of the common source line CSL, and the dummy contact plugs DCP may be formed in a process step that is the same as, or similar to, that of the second input/output contact plug 303. Accordingly, an overall process for forming the vertical capacitor VC may be simplified.

FIG. 6 is a sectional view illustrating one example of the first vertical capacitor structure VCS1 of FIG. 5. For convenience of description, only first to third conductive lines CL1, CL2, and CL3 formed in one metal layer are illustrated in FIG. 6. However, this is illustrative, and at least one metal layer may be additionally formed on the metal layer in which the first to third conductive lines CL1, CL2, and CL3 are formed.

Referring to FIG. 6, first and second active patterns AP1 and AP2 may be defined in the peripheral circuit region PERI, and a channel region may be defined between the first and second active patterns AP1 and AP2. First to third capacitor electrodes MC1, MC2, and MC3 may be disposed on the first active pattern AP1, a gate pattern GP, and the second active pattern AP2, respectively, and the first to third conductive lines CL1, CL2, and CL3 may be disposed on the first to third capacitor electrodes MC1, MC2, and MC3, respectively.

Upper metal patterns PMP1 to PMP4 having the same shape as upper metal patterns CMP1 to CMP4 of the cell region CELL may be formed in the uppermost metal layer of the peripheral circuit region PERI. The first, third, and fourth metal patterns PMP1, PMP3, and PMP4 of the peripheral circuit region PERI may be electrically connected to the first to third conductive lines CL1, CL2, and CL3 through contacts, respectively.

In the cell region CELL, the dummy contact plugs DCP1 to DCP4 may extend in the third direction (the Z-axis direction) and may be electrically connected to the metal patterns CMP1 to CMP4 formed in the uppermost metal layer of the cell region CELL. The upper metal patterns CMP1 to CMP4 of the cell region CELL and the upper metal patterns PMP1 to PMP4 of the peripheral circuit region PERI may have the same shape and may be electrically connected to each other by a bonding method.

The dummy common source lines DCSL4 to DCSL6 may be spaced apart from each other in the second direction (the Y-axis direction). The first dummy contact plug DCP1 may be disposed to correspond to the fourth dummy common source line DCSL4, the second and third dummy contact plugs DCP2 and DCP3 may be disposed to correspond to the fifth dummy common source line DCSL5, and the fourth dummy contact plug DCP4 may be disposed to correspond to the sixth dummy common source line DCSL6. Accordingly, the first dummy contact plug DCP1 may be electrically connected to the first capacitor electrode MC1, the second and third dummy contact plugs DCP2 and DCP3 may be electrically connected to the second capacitor electrode MC2, and the fourth dummy contact plug DCP4 may be electrically connected to the third capacitor electrode MC3.

In some example embodiments, the second voltage V2 may be applied to the first and third conductive lines CL1 and CL3 of the peripheral circuit region PERI, and the first voltage V1 different from the second voltage V2 may be applied to the second conductive line CL2. Accordingly, the first voltage V1 may be applied to the gate pattern GP, and the second voltage V2 may be applied to the first and second active patterns AP1 and AP2. Since the same voltage (i.e., the second voltage V2) is applied to the first and second active patterns AP1 and AP2 as described above, a turn-on current may not flow in the channel region, and charges of the channel region may be in a trapped state. Accordingly, the gate pattern GP and the first and second active patterns AP1 and AP2 may not constitute a MOS transistor.

In this case, the first capacitor electrode MC1 and the second capacitor electrode MC2 of the peripheral circuit region PERI may constitute a first vertical capacitor VC1, and the second capacitor electrode MC2 and the third capacitor electrode MC3 may constitute a second vertical capacitor VC2. In addition, the first dummy contact plug DCP1 and the second dummy contact plug DCP2 of the cell region CELL may constitute a third vertical capacitor VC3, and the third dummy contact plug DCP3 and the fourth dummy contact plug DCP4 may constitute a fourth vertical capacitor VC4. The fourth dummy common source line DCSL4 and the fifth dummy common source line DCSL5 may constitute a fifth vertical capacitor VC5, and the fifth dummy common source line DCSL5 and the sixth dummy common source line DCSL6 may constitute a sixth capacitor VC6.

As described above, the first vertical capacitor structure VCS1 according to this example embodiment may implement the first to sixth vertical capacitors VC1 to VC6 and thus may increase capacitance per unit area. In particular, the first vertical capacitor structure VCS1 according to this example embodiment may additionally obtain the third to sixth vertical capacitors VC3 to VC6 by arranging the dummy contact plugs DCP1 to DCP4 in the cell region CELL and connecting the dummy contact plugs DCP1 to DCP4 to the capacitor electrodes MC1 to MC3 of the peripheral circuit region PERI. In particular, since the capacitances of the third to sixth vertical capacitors VC3 to VC6 are proportional to the height level of the cell region CELL, the capacitances may increase as the number of stages of word lines in the cell region CELL increases.

Meanwhile, it has been described in FIG. 6 that the two dummy contact plugs DCP2 and DCP3 correspond to the fifth dummy common source line DCSL5. However, this is illustrative, and only one dummy contact plug may be disposed on one dummy common source line. Alternatively, three or more dummy contact plugs may be disposed on one dummy common source line.

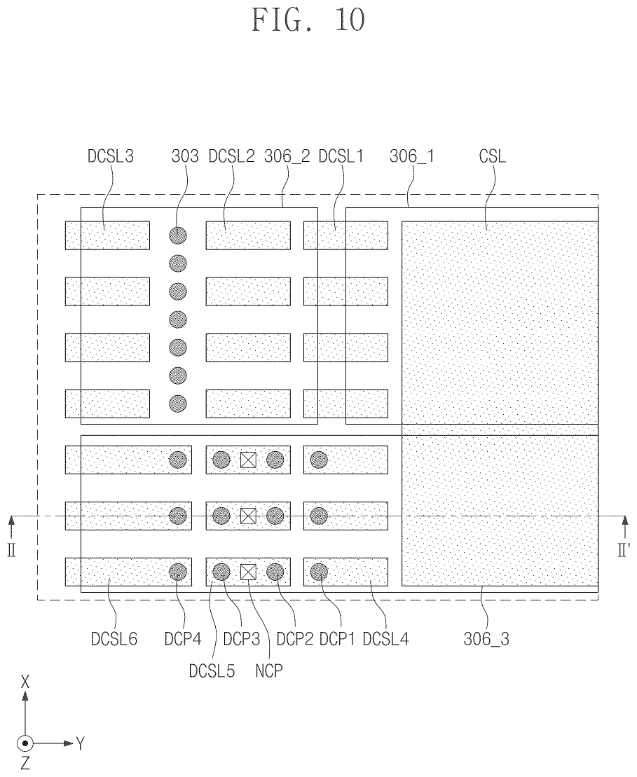

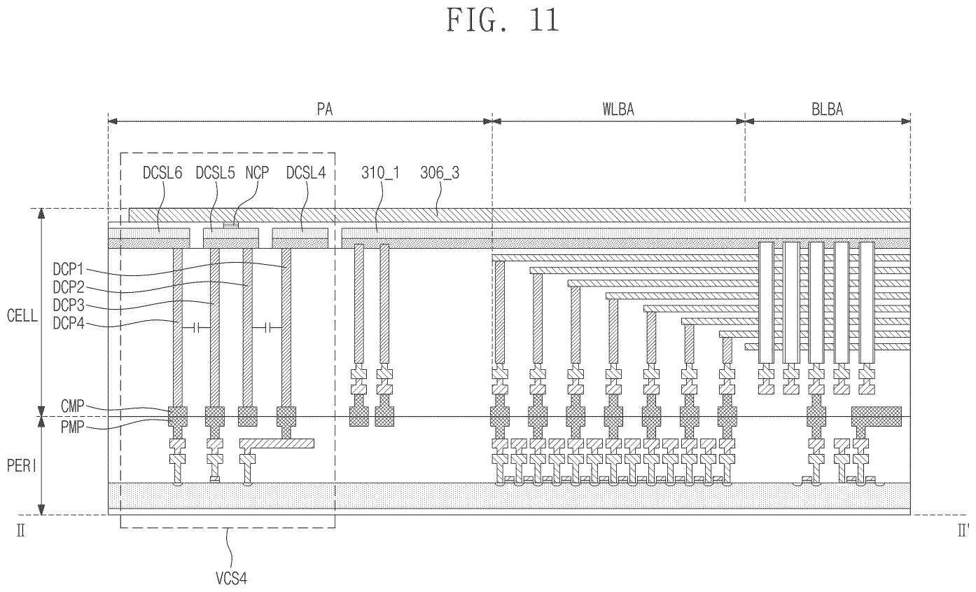

Furthermore, in FIG. 6, the peripheral circuit region PERI of the first vertical capacitor structure VCS1 is illustrated as including the gate pattern GP. However, this is illustrative, and the present disclosure is not limited thereto. For example, as will be described with reference to FIGS. 10 and 11, the peripheral circuit region PERI of the first vertical capacitor structure VCS1 may not include the gate pattern GP. In addition, the peripheral circuit region PERI of the first vertical capacitor structure VCS1 may be implemented in various ways.

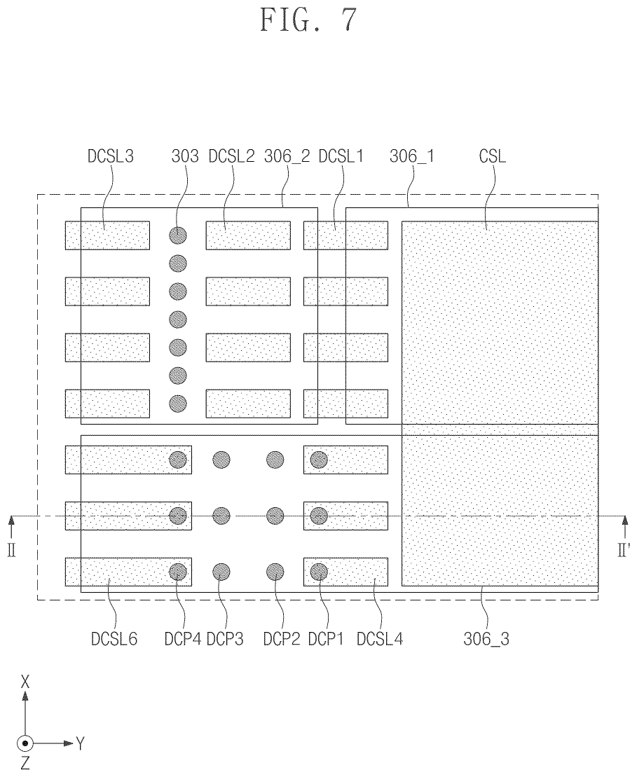

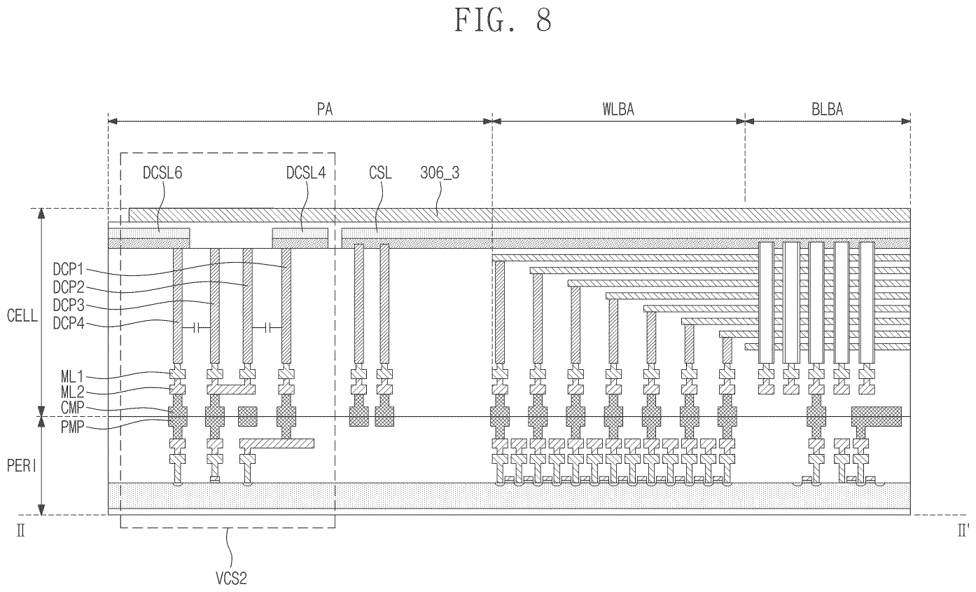

FIG. 7 is a plan view illustrating one example of region R of FIG. 2 according to some example embodiments of the present disclosure, and FIG. 8 illustrates one example of a sectional view taken along line II-II′ of FIG. 7. FIGS. 7 and 8 are similar to the plan view of FIG. 3 and the sectional view of FIG. 5, respectively. Accordingly, identical or similar components will be assigned with identical or similar reference numerals, and repetitive descriptions will hereinafter be omitted.

Referring to FIGS. 7 and 8, a second vertical capacitor structure VCS2 may be formed in a region other than the region in which the second input/output pad 3602 is disposed in the external pad bonding region PA. However, unlike the first vertical capacitor structure VCS1 of FIG. 5, the second vertical capacitor structure VCS2 may not include the fifth dummy common source line DCSL5.

In this case, the second dummy contact plug DCP2 and the third dummy contact plug DCP3 may be electrically connected to each other through a metal line of the cell region CELL. That is, the second dummy contact plug DCP2 and the third dummy contact plug DCP3 of the first vertical capacitor structure VCS1 of FIG. 5 may be electrically connected to each other through the fifth dummy common source line DCSL5, whereas the second dummy contact plug DCP2 and the third dummy contact plug DCP3 of the second vertical capacitor structure VCS2 may be electrically connected to each other through the metal line of the cell region CELL.

For example, as illustrated in FIG. 8, a first metal line ML1 may be formed on the upper portions of the dummy contact plugs DCP1 to DCP4, and a second metal line ML2 may be formed on the first metal line ML1. The second dummy contact plug DCP2 and the third dummy contact plug DCP3 may be electrically connected to each other through the second metal line ML2 extending in the second direction (e.g., the Y-axis direction). However, this is illustrative. The first metal line ML1 may extend in the second direction (the Y-axis direction), and the second dummy contact plug DCP2 and the third dummy contact plug DCP3 may be electrically connected to each other by the first metal line ML1. As the second dummy contact plug DCP2 and the third dummy contact plug DCP3 are electrically connected to each other by the metal line, the second dummy contact plug DCP2 and the third dummy contact plug DCP3 may function as electrodes of the vertical capacitor VC (e.g., be configured to operate as electrodes of the vertical capacitor VC) even without the fifth dummy common source line DCSL5.

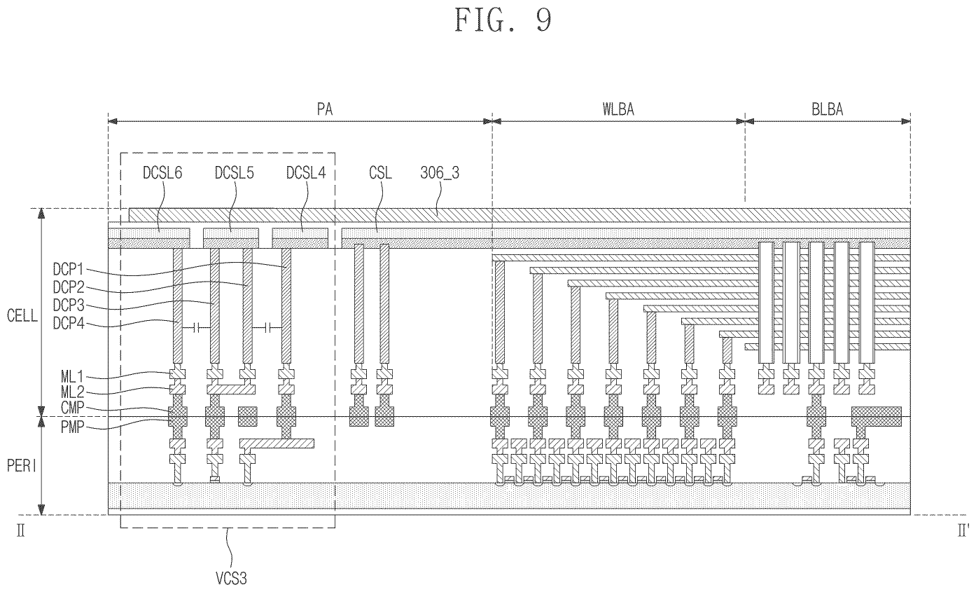

FIG. 9 illustrates one example of a sectional view taken along line II-II′ of FIG. 3. FIG. 9 is similar to the sectional view of FIG. 8. Accordingly, identical or similar components will be assigned with identical or similar reference numerals, and repetitive descriptions will hereinafter be omitted.

Referring to FIGS. 3 and 9, a third vertical capacitor structure VCS3 may be formed in a region other than the region in which the second input/output pad 3602 is disposed in the external pad bonding region PA. However, unlike the second vertical capacitor structure VCS2 of FIG. 8, the third vertical capacitor structure VCS3 may include both the metal line and the fifth dummy common source line DCSL5 that electrically connect the dummy contact plugs DCP2 and DCP3.

For example, as illustrated in FIG. 9, first ends of the second and third dummy contact plugs DCP2 and DCP3 may be electrically connected to each other by the fifth dummy common source line DCSL5, and second ends of the second and third dummy contact plugs DCP2 and DCP3 may be electrically connected to each other through the second metal line ML2. The second and third dummy contact plugs DCP2 and DCP3 may be more stably connected to each other.

FIG. 10 is a plan view illustrating one example of region R of FIG. 2 according to some example embodiments of the present disclosure, and FIG. 11 illustrates one example of a sectional view taken along line II-II′ of FIG. 10. FIGS. 10 and 11 are similar to the plan view of FIG. 3 and the sectional view of FIG. 5, respectively. Accordingly, identical or similar components will be assigned with identical or similar reference numerals, and repetitive descriptions will hereinafter be omitted.

Referring to FIGS. 10 and 11, a fourth vertical capacitor structure VCS4 may be formed in a region other than the region in which the second input/output pad 360_2 is disposed in the external pad bonding region PA. At least a part of the dummy contact plugs DCP1 to DCP4 of the fourth vertical capacitor structure VCS4 may be electrically connected with a third conductive layer 3063 disposed on the bottom surface of the upper insulating layer 301.

For example, as illustrated in FIG. 11, a network contact plug NCP may be formed between the fifth dummy common source line DCSL5 and the third conductive layer 306_3. The network contact plug NCP may penetrate the upper insulating layer 301 and may electrically connect the fifth dummy common source line DCSL5 and the third conductive layer 3063. The network contact plug NCP may be formed through a process step separate from that of the third conductive layer 3063, or may be formed in the same process step as that of the third conductive layer 306_3.

In some example embodiments, the first voltage level V1 (refer to FIG. 6) may be provided to the second and third dummy contact plugs DCP2 and DCP3 through the third conductive layer 3063. That is, the third conductive layer 3063 may be used as a network for the fourth vertical capacitor structure VCS4. In this case, the first voltage may not be provided to the second conductive line CL2 (refer to FIG. 6) of the peripheral circuit region PERI, or the second conductive line CL2 and the gate pattern GP electrically connected thereto may not be formed. Furthermore, in some example embodiments, various voltage levels or powers may be provided to the fourth vertical capacitor structure VCS4 through the third conductive layer 306_3.

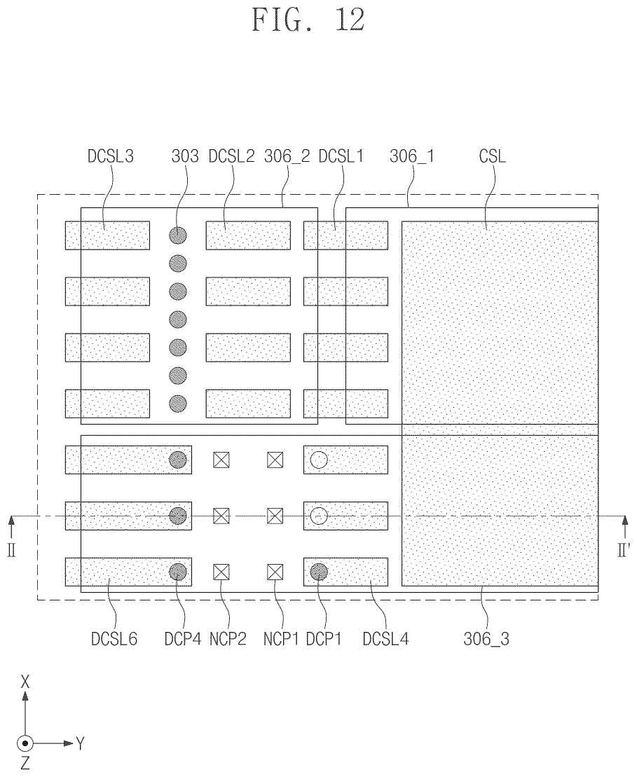

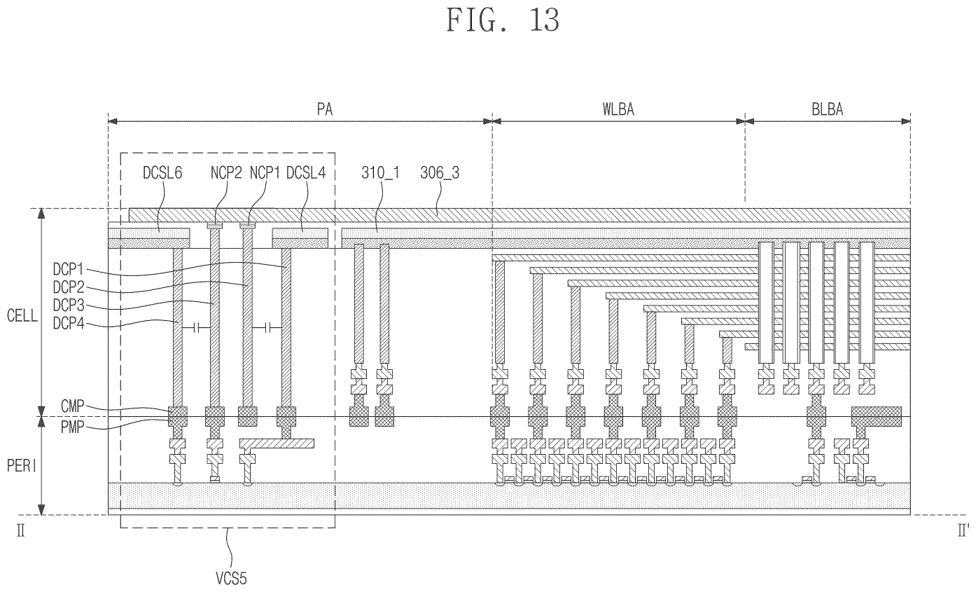

FIG. 12 is a plan view illustrating one example of region R of FIG. 2 according to some example embodiments of the present disclosure, and FIG. 13 illustrates one example of a sectional view taken along line II-II′ of FIG. 12. FIGS. 12 and 13 are similar to the plan view of FIG. 10 and the sectional view of FIG. 11, respectively. Accordingly, identical or similar components will be assigned with identical or similar reference numerals, and repetitive descriptions will hereinafter be omitted.

Referring to FIGS. 12 and 13, a fifth vertical capacitor structure VCS5 may be formed in a region other than the region in which the second input/output pad 360_2 is disposed in the external pad bonding region PA. Unlike the fourth vertical capacitor structure VCS4 of FIG. 11, the fifth vertical capacitor structure VCS5 may not include the fifth dummy common source line DCSL5 (refer to FIG. 11). At least a part of the dummy contact plugs DCP1 to DCP4 of the fifth vertical capacitor structure VCS5 may penetrate at least a portion of the upper insulating layer 301 and may be electrically connected with the third conductive layer 306_3.

For example, as illustrated in FIG. 13, on a top surface of the third conductive layer 3063, first and second network contact plugs NCP1 and NCP2 may be formed between the fourth and sixth dummy common source lines DCSL4 and DCSL6. The third and fourth dummy contact plugs DCP3 and DCP4 may be connected to the third conductive layer 306_3 through the first and second network contact plugs NCP1 and NCP2. Accordingly, the third conductive layer 3063 may be used as a network for the fifth vertical capacitor structure VCS5, and the first voltage level V1 may be provided to the second and third dummy contact plugs DCP2 and DCP3.

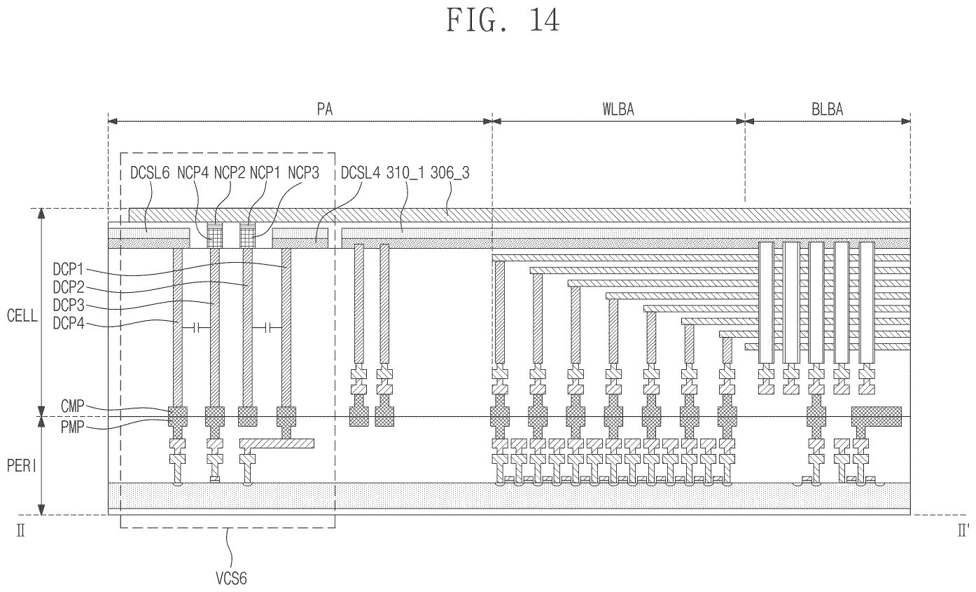

FIG. 14 illustrates another example of a sectional view taken along line II-II′ of FIG. 12. FIG. 14 is similar to the sectional view of FIG. 13. Accordingly, identical or similar components will be assigned with identical or similar reference numerals, and repetitive descriptions will hereinafter be omitted.

Referring to FIG. 14, a sixth vertical capacitor structure VCS6 may be formed in a region other than the region in which the second input/output pad 3602 is disposed in the external pad bonding region PA. However, unlike in the fifth vertical capacitor structure VCS5 of FIG. 13, the dummy contact plugs DCP1 to DCP4 may all have the same height in the sixth vertical capacitor structure VCS6.

For example, the second and third dummy contact plugs DCP2 and DCP3 electrically connected to the third conductive layer 3063 may have the same height as the first and fourth dummy contact plugs DCP1 and DCP4. In this case, the second dummy contact plug DCP2 may be connected to the third conductive layer 306_3 through first and third network contact plugs NCP1 and NCP3, and the third dummy contact plug DCP3 may be connected to the third conductive layer 3063 through second and fourth network contact plugs NCP2 and NCP4.

The third and fourth network contact plugs NCP3 and NCP4 may be formed at the same height as the dummy common source lines DCSL4 and DCSL6, and the first and second network contact plugs NCP1 and NCP2 may be formed on bottom surfaces of the third and fourth network contact plugs NCP3 and NCP4, respectively. However, this is illustrative. The first and third network contact plugs NCP1 and NCP3 may be integrally formed with each other, and the second and fourth network contact plugs NCP2 and NCP4 may be integrally formed with each other.

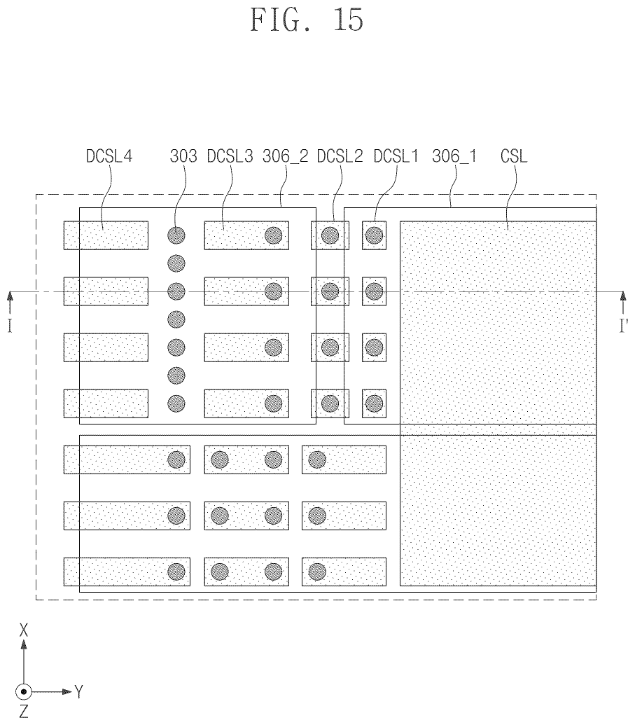

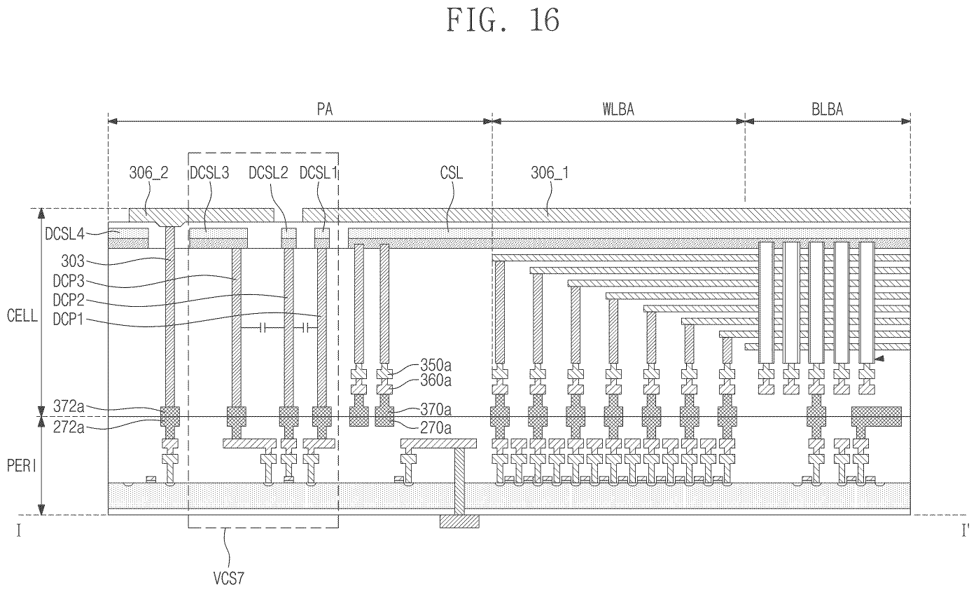

Meanwhile, it has been described in FIGS. 1 to 14 that the electrodes of the vertical capacitor VC are formed in the region not overlapping the second input/output pad 306_2. However, this is illustrative, and as will be described with reference to FIGS. 15 and 16, the electrodes of the vertical capacitor VC may be formed even in a region overlapping the second input/output pad 306_2.

FIG. 15 is a plan view illustrating one example of region R of FIG. 2 according to some example embodiments of the present disclosure, and FIG. 16 illustrates one example of a sectional view taken along line I-I′ of FIG. 15. FIGS. 15 and 16 are similar to the plan view of FIG. 3 and the sectional view of FIG. 4, respectively. Accordingly, identical or similar components will be assigned with identical or similar reference numerals, and repetitive descriptions will hereinafter be omitted.

Referring to FIGS. 15 and 16, a seventh vertical capacitor structure VCS7 may be formed in the external pad bonding region PA. At least some of the dummy common source lines DCSL1 to DCSL3 and the dummy contact plugs DCP1 to DCP3 constituting the seventh vertical capacitor structure VCS7 may overlap the second input/output pad 306_2 when viewed on the plane.

For example, the seventh vertical capacitor structure VCS7 may include the first to third dummy common source lines DCSL1 to DCSL3 and the first to third dummy contact plugs DCP1 to DCP3 connected thereto. The first to third dummy common source lines DCSL1 to DCSL3 may be electrically isolated from each other and may be disposed between the fourth dummy common source line DCSL4 and the common source line CSL.

The third dummy contact plug DCP3 and the third dummy common source line DCSL3 connected thereto, which are used as an electrode of the vertical capacitor VC, may completely overlap the second input/output pad 3062 when viewed on the plane. Furthermore, the second dummy contact plug DCP2 and at least a portion of the second dummy common source line DCSL2 connected thereto, which are used as an electrode of the vertical capacitor VC, may overlap the second input/output pad 306_2 when viewed on the plane. However, this is illustrative, and the second dummy contact plug DCP2 and the second dummy common source line DCSL2 connected thereto may completely overlap the second input/output pad 306_2.

As described above, the vertical capacitor structure according to some example embodiments of the present disclosure may be formed even in the region in which the input/output pad 3062 is formed in the external pad bonding region PA.

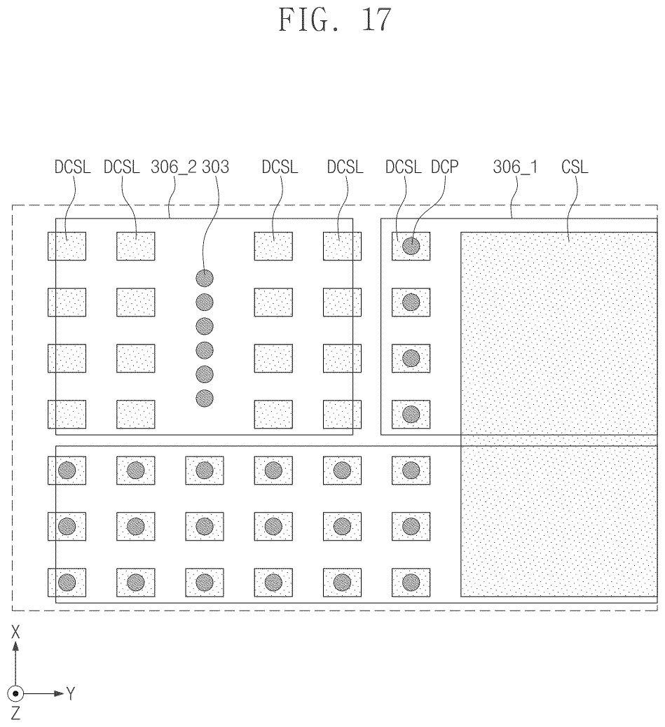

Meanwhile, the arrangement of the dummy common source lines DCSL and the dummy contact plugs DCP constituting the vertical capacitor structure may be diversely modified. Hereinafter, various arrangement methods according to some example embodiments of the present disclosure will be described in more detail with reference to FIGS. 17 to 19.

FIGS. 17 to 19 are views illustrating examples of region R of FIG. 2 according to some example embodiments of the present disclosure. FIGS. 17 to 19 are similar to the plan view of FIG. 3. Accordingly, identical or similar components will be assigned with identical or similar reference numerals, and repetitive descriptions will hereinafter be omitted.

Referring to FIG. 17, the dummy common source lines DCSL and the dummy contact plugs DCP constituting the vertical capacitor VC may be formed in most regions other than the region in which the second input/output pad 306_2 is formed.

For example, the dummy common source lines DCSL and the dummy contact plugs DCP connected thereto, which constitute the vertical capacitor VC, may be disposed in the first direction (the X-axis direction) between the second input/output pad 3062 and the common source line CSL. Furthermore, the dummy common source lines DCSL and the dummy contact plugs DCP connected thereto, which constitute the vertical capacitor VC, may be disposed between the second input/output pads 3062 disposed in the first direction. In addition, one dummy common source line DCSL may be connected to one dummy contact plug DCP.

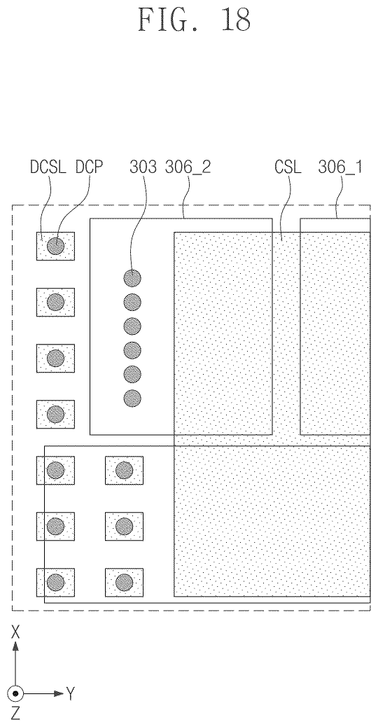

Referring to FIG. 18, the second input/output pad 3062, when viewed on the plane, may not completely overlap the dummy common source line DCSL. For example, the second input/output pad 306_2 may at least partially overlap the common source line CSL when viewed on the plane, but may not completely overlap the dummy common source line DCSL. The second input/output contact plugs 303 connected with the second input/output pad 3062 may be disposed in the first direction (the X-axis direction) on one side of the common source line CSL.

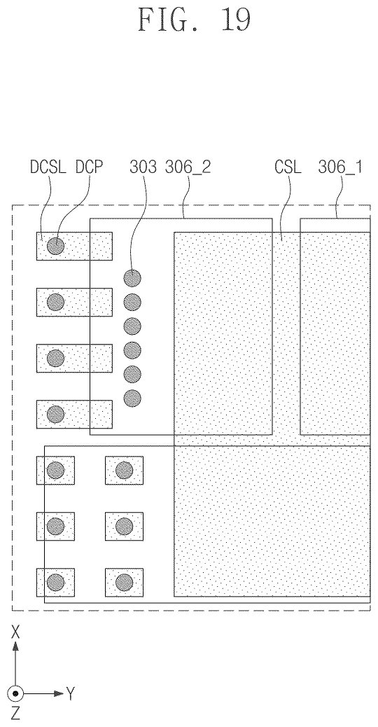

Referring to FIG. 19, the second input/output pad 3062, when viewed on the plane, may partially overlap the dummy common source line DCSL. For example, the second input/output pad 306_2, when viewed on the plane, may partially overlap the common source line CSL and may partially overlap the dummy common source line DCSL.

Meanwhile, it has been described in FIGS. 1 to 19 that the non-volatile memory device 100 is formed by coupling one lower chip and one upper chip by a bonding method. However, this is illustrative, and the non-volatile memory device 100 may have a structure two or more upper chips are coupled to one lower chip by a bonding method. Hereinafter, detailed description thereabout will be given.

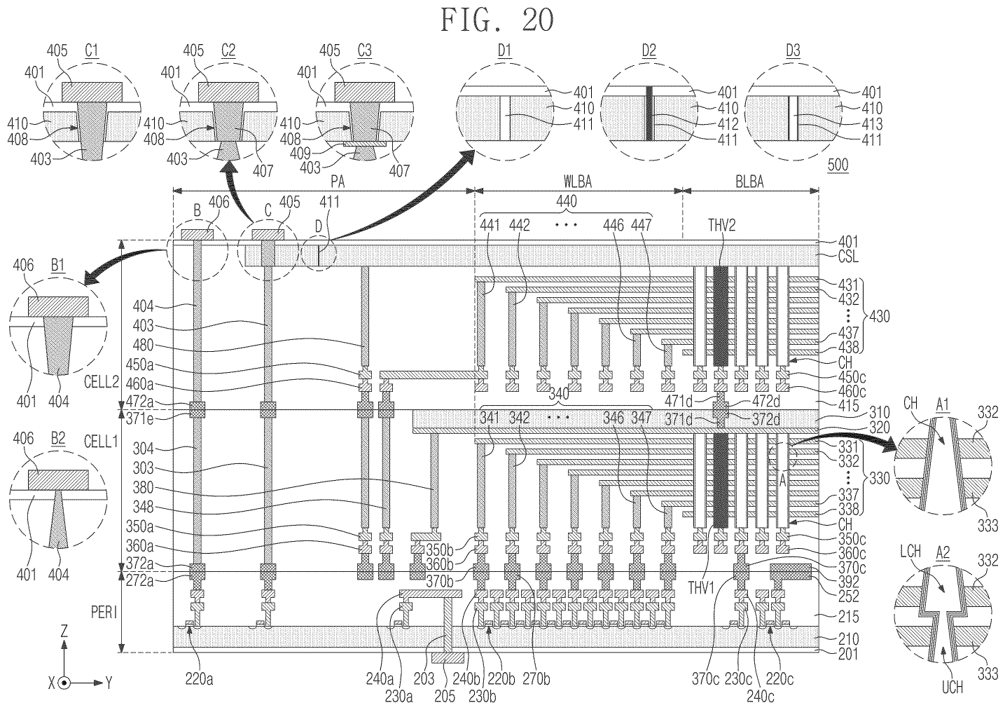

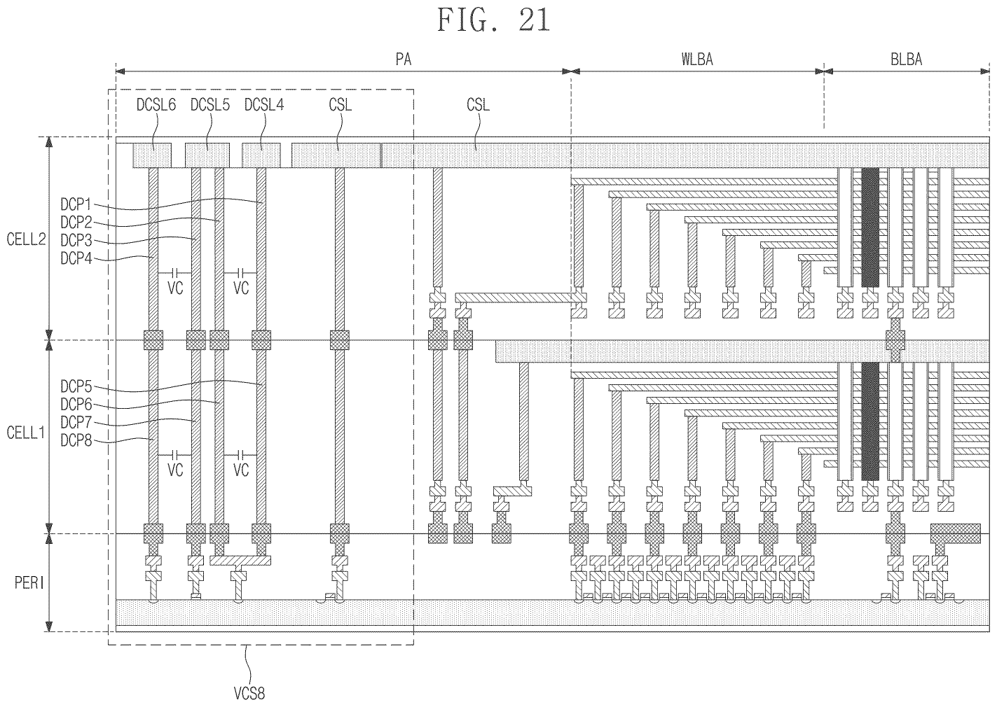

FIGS. 20 and 21 are sectional views illustrating one example of a non-volatile memory device 500 according to some example embodiments of the present disclosure. FIG. 20 is similar to the sectional view of FIG. 4, and FIG. 21 is similar to the sectional view of FIG. 5. Accordingly, identical or similar components will be assigned with identical or similar reference numerals, and repetitive descriptions will hereinafter be omitted.

Referring to FIG. 20, the non-volatile memory device 500 may be implemented to include two upper chips. In this case, the non-volatile memory device 500 may be manufactured by manufacturing a first upper chip including a first cell region CELL1, a second upper chip including a second cell region CELL2, and a lower chip including a peripheral circuit region PERI and thereafter connecting the first upper chip, the second upper chip, and the lower chip by a bonding method. The first upper chip may be turned over and connected to the lower chip by a bonding method, and the second upper chip may also be turned over and connected to the first upper chip by a bonding method.

Each (or alternatively, at least one) of the first and second cell regions CELL1 and CELL2 may include at least one memory block. The first cell region CELL1 may include a common source line CSL having a plate shape extending in the X-axis direction and the Y-axis direction. The common source line CSL may include a metallic material and may include, for example, tungsten (W), aluminum (Al), copper (Cu), tungsten nitride (WN), tantalum nitride (TaN), a titanium nitride (TiN), or a combination thereof.

A plurality of word lines 330 (331 to 338) may be stacked on a top surface of the common source line CSL in the Z-axis direction. String selection lines and a ground selection line may be disposed on and under the word lines 330, and the plurality of word lines 330 may be disposed between the string selection lines and the ground selection line.

Likewise, the second cell region CELL2 may include a common source line CSL, and a plurality of word lines 430 (431 to 438) may be stacked in the Z-axis direction. A plurality of channel structures CH may be formed in the first and second cell regions CELL1 and CELL2. In some example embodiments, as illustrated in A1, the channel structure CH may be provided in a bit line bonding region BLBA and may extend in the Z-axis direction to penetrate the word lines 330, the string selection lines, and the ground selection line. The channel structure CH may include data storage layer, a channel layer, and a buried insulating layer. The channel layer may be electrically connected with a first metal line 350c and a second metal line 360c in the bit line bonding region BLBA. For example, the second metal line 360c may be a bit line and may be connected to the channel structure CH through the first metal line 350c. The bit line 360c may extend in a first direction (the Y-axis direction) parallel to or substantially parallel to a top surface of a second substrate 310.

In some example embodiments, as illustrated in A2, the channel structure CH may include a lower channel LCH and an upper channel UCH connected to each other. For example, the channel structure CH may be formed through a process for the lower channel LCH and a process for the upper channel UCH. The lower channel LCH may extend in the Z-axis direction and may penetrate a common source line 320 and the lower word lines 331 and 332. The lower channel LCH may include a data storage layer, a channel layer, and a buried insulating layer and may be connected with the upper channel UCH. The upper channel UCH may penetrate the upper word lines 333 to 338. The upper channel UCH may include a data storage layer, a channel layer, and a buried insulating layer, and the channel layer of the upper channel UCH may be electrically connected with the first metal line 350c and the second metal line 360c. As the length of a channel increases, it may be difficult to form a channel having a constant width due to process reasons. The non-volatile memory device 500 according to some example embodiments of the present disclosure may include a channel having improved width uniformity through the lower channel LCH and the upper channel UCH formed by sequential processes.

In the case in which the channel structure CH includes the lower channel LCH and the upper channel UCH as illustrated in A2, a word line located near the boundary between the lower channel LCH and the upper channel UCH may be a dummy word line. For example, the word line 332 and the word line 333 that form the boundary between the lower channel LCH and the upper channel UCH may be dummy word lines. In this case, data may not be stored in memory cells connected to the dummy word lines. Alternatively, the number of pages corresponding to the memory cells connected to the dummy word lines may be smaller than the number of pages corresponding to memory cells connected to normal word lines. A voltage level applied to the dummy word lines may differ from a voltage level applied to the normal word lines, and thus an influence of a non-uniform channel width between the lower channel LCH and the upper channel UCH on an operation of the memory device may be reduced.

Meanwhile, it is illustrated in A2 that the number of lower word lines 331 and 332 penetrated by the lower channel LCH is smaller than the number of upper word lines 333 to 338 penetrated by the upper channel UCH. However, this is illustrative, and the present disclosure is not limited thereto. In another example, the number of lower word lines penetrated by the lower channel LCH may be equal to or greater than the number of upper word lines penetrated by the upper channel UCH. Furthermore, the structure and connection relationship of the channel structure CH disposed in the first cell region CELL1 described above may be identically applied to the channel structure CH disposed in the second cell region CELL2.

In the bit line bonding region BLBA, a first through-electrode THV1 may be provided in the first cell region CELL1, and a second through-electrode THV2 may be provided in the second cell region CELL2. As illustrated in FIG. 20, the first through-electrode THV1 may penetrate the common source line CSL. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some example embodiments, the first through-electrode THV1 and the second through-electrode THV2 may be electrically connected through a first through-metal pattern 372d and a second through-metal pattern 472d. The first through-metal pattern 372d may be formed at a bottom end of the first upper chip including the first cell region CELL1, and the second through-metal pattern 472d may be formed at a top end of the second upper chip including the second cell region CELL2. The first through-electrode THV1 may be electrically connected with the first metal line 350c and the second metal line 360c. A lower VIA 371d may be formed between the first through-electrode THV1 and the first through-metal pattern 372d, and an upper VIA 471d may be formed between the second through-electrode THV2 and the second through-metal pattern 472d. The first through-metal pattern 372d and the second through-metal pattern 472d may be connected by a bonding method.

In a word line bonding region WLBA, the word lines 330 of the first cell region CELL1 may extend in the X-axis direction and may be connected with a plurality of cell contact plugs 340 (341 to 347). A first metal line 350b and a second metal line 360b may be sequentially connected to upper portions of the cell contact plugs 340 connected to the word lines 330. In the word line bonding region WLBA, the cell contact plugs 340 may be connected with the peripheral circuit region PERI through an upper bonding metal 370b of the first cell region CELL1 and an upper bonding metal 270b of the peripheral circuit region PERI.

In the word line bonding region WLBA, the word lines 430 of the second cell region CELL2 may extend in the X-axis direction and may be connected with a plurality of cell contact plugs 440 (441 to 447). The cell contact plugs 440 may be connected with the peripheral circuit region PERI through an upper metal pattern of the second cell region CELL2, a lower metal pattern and an upper metal pattern of the first cell region CELL1, and a cell contact plug 348.

In an external pad bonding region PA, a lower metal pattern 371e may be formed in a lower portion of the first cell region CELL1, and an upper metal pattern 472a may be formed in an upper portion of the second cell region CELL2. The lower metal pattern 371e of the first cell region CELL1 and the upper metal pattern 472a of the second cell region CELL2 may be connected by a bonding method in the external pad bonding region PA. Likewise, an upper metal pattern 372a may be formed in an upper portion of the first cell region CELL1, and an upper metal pattern 272a may be formed in an upper portion of the peripheral circuit region PERI. The upper metal pattern 372a of the first cell region CELL1 and the upper metal pattern 272a of the peripheral circuit region PERI may be connected to each other by a bonding method.

Common source line contact plugs 380 and 480 may be disposed in the external pad bonding region PA. The common source line contact plugs 380 and 480 may be formed of or include a conductive material, such as metal, a metal compound, or doped poly-silicon. The common source line contact plug 380 of the first cell region CELL1 may be electrically connected with the common source line 320, and the common source line contact plug 480 of the second cell region CELL2 may be electrically connected with a common source line 420. A first metal line 350a and a second metal line 360a may be stacked (e.g., sequentially stacked) on an upper portion of the common source line contact plug 380 of the first cell region CELL1, and a first metal line 450a and a second metal line 460a may be stacked (e.g., sequentially stacked) on an upper portion of the common source line contact plug 480 of the second cell region CELL2.

Input/output pads 205, 405, and 406 may be disposed in the external pad bonding region PA. Referring to FIG. 20, a lower insulating layer 201 may cover a bottom surface of the first substrate 210, and the first input/output pad 205 may be formed on the lower insulating layer 201. The first input/output pad 205 may be connected with at least one of a plurality of circuit elements 220a disposed in the peripheral circuit region PERI through a first input/output contact plug 203 and may be separated from the first substrate 210 by the lower insulating layer 201. In addition, a side insulating layer may be disposed between the first input/output contact plug 203 and the first substrate 210 and may electrically isolate the first input/output contact plug 203 from the first substrate 210.

An upper insulating layer 401 may be formed on a third substrate 410 to cover a top surface of the third substrate 410. The second input/output pad 405 and/or the third input/output pad 406 may be disposed on the upper insulating layer 401. The second input/output pad 405 may be connected with at least one of the plurality of circuit elements 220a disposed in the peripheral circuit region PERI through second input/output contact plugs 403 and 303, and the third input/output pad 406 may be connected with at least one of the plurality of circuit elements 220a disposed in the peripheral circuit region PERI through third input/output contact plugs 404 and 304.

In some example embodiments, the third substrate 410 may not be disposed in the regions in which the input/output contact plugs are disposed. For example, as illustrated in B, the third input/output contact plug 404 may be separated from the third substrate 410 in a direction parallel to or substantially parallel to the top surface of the third substrate 410 and may be connected to the third input/output pad 406 through an interlayer insulating layer 415 of the second cell region CELL2. In this case, the third input/output contact plug 404 may be formed through various processes.

For example, as illustrated in B1, the third input/output contact plug 404 may extend in a third direction (the Z-axis direction) and may have an increasing diameter toward the upper insulating layer 401. That is, while the channel structure CH described with reference to A1 has a decreasing diameter toward the upper insulating layer 401, the third input/output contact plug 404 may have an increasing diameter toward the upper insulating layer 401. For example, the third input/output contact plug 404 may be formed after the second cell region CELL2 and the first cell region CELL1 are coupled by a bonding method.

For example, as illustrated in B2, the third input/output contact plug 404 may extend in the third direction (the Z-axis direction) and may have a decreasing diameter toward the upper insulating layer 401. That is, likewise to the channel structure CH, the third input/output contact plug 404 may have a decreasing diameter toward the upper insulating layer 401. For example, the third input/output contact plug 404 may be formed together with the cell contact plugs 440 before the second cell region CELL2 and the first cell region CELL1 are coupled by a bonding method.

In some example embodiments, an input/output contact plug may be disposed to overlap the third substrate 410. For example, as illustrated in C, the second input/output contact plug 403 may be formed through the interlayer insulating layer 415 of the second cell region CELL2 in the third direction (the Z-axis direction) and may be electrically connected to the second input/output pad 405 through the third substrate 410. In this case, a connection structure of the second input/output contact plug 403 and the second input/output pad 405 may be implemented in various ways.

For example, as illustrated in C1, an opening 408 may be formed through the third substrate 410, and the second input/output contact plug 403 may be directly connected to the second input/output pad 405 through the opening 408 formed in the third substrate 410. In this case, as illustrated in C1, the second input/output contact plug 403 may have an increasing diameter toward the second input/output pad 405. However, this is illustrative, and the second input/output contact plug 403 may have a decreasing diameter toward the second input/output pad 405.

For example, as illustrated in C2, the opening 408 may be formed through the third substrate 410, and a contact 407 may be formed in the opening 408. One end portion of the contact 407 may be connected to the second input/output pad 405, and an opposite end portion of the contact 407 may be connected to the second input/output contact plug 403. Accordingly, the second input/output contact plug 403 may be electrically connected to the second input/output pad 405 through the contact 407 in the opening 408. In this case, as illustrated in C2, the contact 407 may have an increasing diameter toward the second input/output pad 405, and the second input/output contact plug 403 may have a decreasing diameter toward the second input/output pad 405. For example, the third input/output contact plug 403 may be formed together with the cell contact plugs 440 before the second cell region CELL2 and the first cell region CELL1 are coupled by a bonding method, and the contact 407 may be formed after the second cell region CELL2 and the first cell region CELL1 are coupled by the bonding method.

For example, as illustrated in C3, a stopper 409 may be additionally formed on a top surface of the opening 408 of the third substrate 410. The stopper 409 may be a metal line formed on the same layer as the common source line 420. However, this is illustrative, and the stopper 409 may be a metal line formed on the same layer as at least one of the word lines 430. The second input/output contact plug 403 may be electrically connected to the second input/output pad 405 through the contact 407 and the stopper 409.

Meanwhile, similarly to the second and third input/output contact plugs 403 and 404 of the second cell region CELL2, the second and third input/output contact plugs 303 and 304 of the first cell region CELL1 may have a decreasing diameter toward the lower metal pattern 371e, or may have an increasing diameter toward the lower metal pattern 371e.

Meanwhile, in some example embodiments, a slit 411 may be formed in the third substrate 410. For example, the slit 411 may be formed at any position in the external pad bonding region PA. For example, as illustrated in D, the slit 411 may be located between the second input/output pad 405 and the cell contact plugs 440 when viewed on the plane. However, this is illustrative, and the slit 411 may be formed such that the second input/output pad 405 is located between the slit 411 and the cell contact plugs 440 when viewed on the plane.

For example, as illustrated in D1, the slit 411 may be formed through the third substrate 410. For example, the slit 411 may be used to prevent or hinder the third substrate 410 from being finely cracked when the opening 408 is formed. However, this is illustrative, and the slit 411 may be formed to have a depth ranging from about 60% to about 70% of the thickness of the third substrate 410.

For example, as illustrated in D2, a conductive material 412 may be formed in the slit 411. For example, the conductive material 412 may be used to discharge a leakage current generated while circuit elements in the external pad bonding region PA are driven. In this case, the conductive material 412 may be connected to an external ground line.

For example, as illustrated in D3, an insulating material 413 may be formed in the slit 411. For example, the insulating material 413 may be formed to electrically isolate the second input/output pad 405 and the second input/output contact plug 403 disposed in the external pad bonding region PA from the word line bonding region WLBA. An influence of a voltage provided through the second input/output pad 405 on a metal layer disposed on the third substrate 410 in the word line bonding region WLBA may be interrupted by forming the insulating material 413 in the slit 411.

Meanwhile, in some example embodiments, the first to third input/output pads 205, 405, and 406 may be selectively formed. For example, the memory device 500 may be implemented to include only the first input/output pad 205 disposed on the first substrate 201, only the second input/output pad 405 disposed on the third substrate 401, or only the third input/output pad 406 disposed on the upper insulating layer 401.

Meanwhile, in some example embodiments, at least one of the second substrate 310 of the first cell region CELL1 or the third substrate 410 of the second cell region CELL2 may be used as a sacrificial substrate and may be completely or partially removed before or after a bonding process. An additional layer may be stacked after the removal of the substrate. For example, the second substrate 310 of the first cell region CELL1 may be removed before or after the peripheral circuit region PERI and the first cell region CELL1 are bonded to each other, and an insulating layer for covering a top surface of the common source line 320 or a conductive layer for connection may be formed. Similarly, the third substrate 410 of the second cell region CELL2 may be removed before or after the first cell region CELL1 and the second cell region CELL2 are bonded to each other, and the upper insulating layer 401 for covering a top surface of the common source line 420 or a conductive layer for connection may be formed.

Referring to FIG. 21, the non-volatile memory device 500 according to some example embodiments of the present disclosure may include dummy common source lines DCSL4 to DCSL6 disposed at the same height level as the common source line CSL. The dummy common source lines DCSL4 to DCSL6 may be electrically connected to dummy contact plugs DCP1 to DCP4 formed in the second cell region CELL2 and dummy contact plugs DCP5 to DCP8 formed in the first cell region CELL1 and may form an eighth vertical capacitor structure VCS8 together with the circuit elements formed in the peripheral circuit region PERI. In this case, the length of vertical capacitor electrodes constituting the eighth vertical capacitor structure VCS8 in the Z-axis direction may be increased in proportion to the number of stacked chips. Accordingly, the non-volatile memory device 500 according to some example embodiments of the present disclosure may provide larger capacitance as the number of stacked chips is increased.

The non-volatile memory devices according to the present disclosure may provide large capacitance without an increase in chip size (e.g., a chip size may be reduced or minimized).

The above-described contents are specific example embodiments for carrying out the present disclosure. The present disclosure includes not only the above-described example embodiments but also some example embodiments that can be made through a simple design change or can be easily modified. Furthermore, the present disclosure includes technologies that can be carried out by easily modifying the example embodiments. Accordingly, the scope of the present disclosure should not be determined by the above-described example embodiments and should be determined by the accompanying claims and the equivalents thereof.

Any of the elements and/or functional blocks disclosed above may include or be implemented in processing circuitry such as hardware including logic circuits; a hardware/software combination such as a processor executing software; or a combination thereof. For example, the control logic 123 may be implemented as processing circuitry. The processing circuitry specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Processor(s), controller(s), and/or processing circuitry may be configured to perform actions or steps by being specifically programmed to perform those action or steps (such as with an FPGA or ASIC) or may be configured to perform actions or steps by executing instructions received from a memory, or a combination thereof.

While the present disclosure has been described with reference to some example embodiments thereof, it will be apparent to those of ordinary skill in the art that various changes and modifications may be made thereto without departing from the spirit and scope of the present disclosure as set forth in the following claims.

What is claimed is:

1. A non-volatile memory device comprising:
a first chip having a peripheral circuit therein; and
a second chip stacked on the first chip, the second chip including memory blocks,
wherein the second chip includes
a common source line having a plate shape, the common source line extending in first and second directions,
first and second dummy common source lines at a same height level as the common source line,
an upper insulating layer covering the common source line and the first and second dummy common source lines, and
first and second dummy contact plugs extending in a third direction, the first and second dummy contact plugs being electrically connected to the first and second dummy common source lines, respectively, and used as electrodes of a vertical capacitor.

2. The non-volatile memory device of claim 1, further comprising:
an input/output pad on the upper insulating layer; and
an input/output contact plug extending in the third direction perpendicular to the common source line and electrically connected to the input/output pad,
wherein the input/output contact plug and the first and second dummy contact plugs have a first shape.

3. The non-volatile memory device of claim 2, wherein the first dummy contact plug overlaps the input/output pad in a plane.

4. The non-volatile memory device of claim 3, wherein at least a portion of the first dummy common source line connected with the first dummy contact plug overlaps the input/output pad in the plane.

5. The non-volatile memory device of claim 1, further comprising:
a third dummy common source line disposed at the same height level as the common source line; and
third and fourth dummy contact plugs extending in the third direction and configured as electrodes of the vertical capacitor,
wherein the third dummy contact plug is electrically connected to the second dummy common source line, and the fourth dummy contact plug is electrically connected to the third dummy common source line.

6. The non-volatile memory device of claim 5, further comprising:
control logic configured to cause a first voltage to be applied to the second and third dummy contact plugs, and a second voltage different from the first voltage to be applied to the first and fourth dummy contact plugs.

7. The non-volatile memory device of claim 1, further comprising:
third and fourth dummy contact plugs extending in the third direction and between the first and second dummy contact plugs; and
a metal line on upper portions of the third and fourth dummy contact plugs and extending in the second direction to electrically connect the third and fourth dummy contact plugs to each other.

8. The non-volatile memory device of claim 7, further comprising:
a third dummy common source line at a same height level as the common source line and between the first and second dummy common source lines,
wherein the third and fourth dummy contact plugs are electrically connected to the third dummy common source line.

9. The non-volatile memory device of claim 2, further comprising:
a conductive layer at a same height level as the input/output pad and electrically isolated from the input/output pad; and
a network contact plug penetrating the upper insulating layer and electrically connecting the conductive layer and the second dummy common source line.

10. The non-volatile memory device of claim 9, further comprising:
a third dummy common source line at a same height level as the common source line;
a third dummy contact plug extending in the third direction and connected to the second dummy common source line, the third dummy contact plug being connected to the conductive layer through the second dummy common source line and the network contact plug; and
a fourth dummy contact plug extending in the third direction and electrically connected to the third dummy common source line.

11. The non-volatile memory device of claim 2, further comprising:
a conductive layer at a same height level as the input/output pad and electrically isolated from the input/output pad;
third and fourth dummy contact plugs between the first and second dummy contact plugs and extending in the third direction to electrically connect to the conductive layer;
a first network contact plug between the third dummy contact plug and the conductive layer and electrically connecting the third dummy contact plug and the conductive layer; and
a second network contact plug between the fourth dummy contact plug and the conductive layer and electrically connecting the fourth dummy contact plug and the conductive layer.

12. The non-volatile memory device of claim 11, wherein bottom surfaces of the third and fourth dummy contact plugs at a same height as bottom surfaces of the first and second dummy common source lines.

13. The non-volatile memory device of claim 11, wherein bottom surfaces of the third and fourth dummy contact plugs at a same height as bottom surfaces of the first and second dummy contact plugs.

14. The non-volatile memory device of claim 2, wherein the first and second dummy common source lines and the first and second dummy contact plugs are between the input/output pad and the common source line in a plane.

15. The non-volatile memory device of claim 2, wherein, in a plane,
the input/output pad and portions of the first and second dummy common source lines overlap each other, and
the input/output pad and the first and second dummy contact plugs do not overlap each other.

16. The non-volatile memory device of claim 1, wherein the second chip is inverted and stacked on the first chip.

17. A non-volatile memory device comprising:
a first chip including a peripheral circuit region; and
a second chip stacked on the first chip, the second chip including a cell region,
wherein the second chip includes
a common source line having a plate shape, the common source line extending in first and second directions,
first and second dummy common source lines at a same height level as the common source line and electrically isolated from each other,
an input/output contact plug on one side of the common source line and extending in a third direction perpendicular to the common source line to transfer a signal received from an input/output pad to the first chip, and
first and second dummy contact plugs extending in the third direction and connected to the first and second dummy common source lines, respectively, the first and second dummy contact plugs having a same shape as the input/output contact plugs.

18. The non-volatile memory device of claim 17, wherein at least one of the first and second dummy contact plugs overlaps the input/output pad in a plane.

19. The non-volatile memory device of claim 17, wherein at least portions of the first and second dummy common source lines overlap the input/output pad in a plane.

20. The non-volatile memory device of claim 17, wherein, in a plane,
the input/output pad and portions of the first and second dummy common source lines overlap each other, and
the input/output pad and the first and second dummy contact plugs do not overlap each other.
